(19) United States
(12) Patent Application Publication
(10) Pub. No.: US 2025/0221248 A1
(43) Pub. Date: Jul. 3, 2025

(54) DISPLAY PANEL AND DISPLAY APPARATUS

(71) Applicant: WUHAN CHINA STAR OPTOELECTRONICS SEMICONDUCTOR DISPLAY TECHNOLOGY CO., LTD., Wuhan (CN)

(72) Inventors: Jing CHEN, Wuhan (CN); Qi JIANG, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 18/581,429

(22) Filed: Feb. 20, 2024

Related U.S. Application Data
(63) Continuation of application No. PCT/CN2024/071095, filed on Jan. 8, 2024.

(30) Foreign Application Priority Data
Dec. 29, 2023 (CN) 202311869936.3

(51) Int. Cl. H10K 59/80; H10K 59/38; H10K 102/00

(52) U.S. Cl. CPC H10K 59/872; H10K 59/38; H10K 2102/311

(57) ABSTRACT

A display panel includes a panel body and a protective layer disposed on a light exit side of the panel body. The protective layer includes an ultra-thin glass and a protective structure. The ultra-thin glass has a first surface close to the panel body and a plurality of side surfaces each connected to the first surface. The protective structure covers at least the side surfaces. An orthographic projection of each of the side surfaces on the panel body is offset from a center of the panel body. An absolute value of a difference between a refractive index of the protective structure and a refractive index of the ultra-thin glass is less than or equal to 0.02.

### CROSS-REFERENCE TO RELATED APPLICATIONS

This application is a continuation of International Application No. PCT/CN2024/071095, filed on Jan. 8, 2024, which claims priority to Chinese Patent Application No. 202311869936.3, filed on Dec. 29, 2023. The disclosures of the abovementioned applications are incorporated herein by reference in their entireties.

### TECHNICAL FIELD

The present application relates to display technologies, and in particular to a display panel and a display apparatus.

### BACKGROUND

Foldable display apparatuses represent a trend of future technology development of the display industry. Organic light-emitting diode (OLED) display apparatuses have unique properties of being bendable and foldable, and thus can be used to form foldable display apparatuses in various shapes which are easy to carry and store. Therefore, OLED display apparatuses have been widely concerned in the market.

Generally, ultra-thin glass (UTG) with good flexibility and good optical effects is used in foldable display apparatuses. However, due to fit tolerances and the avoidance of cracking of the ultra-thin glass during a cutting process, the ultra-thin glass cannot cover edges of the display apparatus, so that side edges of the display apparatus are less protected and thus prone to problems, such as damage and failure, due to impact.

### SUMMARY

According to one or more embodiments of the present application, a display panel includes: a panel body; and a protective layer disposed on a light exit side of the panel body, the protective layer including an ultra-thin glass and a protective structure, the ultra-thin glass including a first surface close to the panel body and a plurality of side surfaces each connected to the first surface, the protective structure covering at least the plurality of side surfaces. An orthographic projection of each of the plurality of side surfaces on the panel body is offset from a center of the panel body, and an absolute value of a difference between a refractive index of the protective structure and a refractive index of the ultra-thin glass is less than or equal to 0.02.

According to one or more embodiments of the present application, a display apparatus includes a display panel. The display panel includes: a panel body; and a protective layer disposed on a light exit side of the panel body, the protective layer including an ultra-thin glass and a protective structure, the ultra-thin glass including a first surface close to the panel body and a plurality of side surfaces each connected to the first surface, the protective structure covering at least the plurality of side surfaces. An orthographic projection of each of the plurality of side surfaces on the panel body is offset from a center of the panel body, and an absolute value of a difference between a refractive index of the protective structure and a refractive index of the ultra-thin glass is less than or equal to 0.02.

### BRIEF DESCRIPTION OF THE DRAWINGS

FIG. 1 is a schematic diagram of a structure of a display panel in the related art.

FIG. 2 is a schematic diagram of another structure of a display panel in the related art.

FIG. 3 is a schematic diagram of a structure of a display panel according to one or more embodiments of the present application.

FIG. 4 is a schematic diagram of a structure of a protective layer according to one or more embodiments of the present application.

FIG. 5 is a schematic diagram of another structure of a display panel according to one or more embodiments of the present application.

FIG. 6 is a schematic diagram of yet another structure of a display panel according to one or more embodiments of the present application.

FIG. 7 is a schematic diagram of yet another structure of a display panel according to one or more embodiments of the present application.

FIG. 8 is a schematic diagram of yet another structure of a display panel according to one or more embodiments of the present application.

FIGS. 9 to 27 schematically illustrate a process of manufacturing a display panel according to one or more embodiments of the present application.

FIG. 28 is a block diagram of a display apparatus according to one or more embodiments of the present application.

### DETAILED DESCRIPTION

Some embodiments of the present application will be described in detail below with reference to the accompanying drawings. The embodiments are described for illustrative purposes only and are not intended to limit the present application.

Many different embodiments or examples are disclosed below for implementing various structures in the present application. To simplify the present disclosure, components and arrangements are described in specific examples below. Of course, they are merely examples and are not intended to limit the present application. In addition, in the present application, reference numbers and/or reference letters may be may repeated in different examples, and such repetition is for the purposes of simplicity and clarity and does not by itself indicate a relationship between various embodiments and/or arrangements disclosed. Moreover, examples of various specific processes and materials are provided in the present application, but one of ordinary skill in the art can see the application of other processes and/or the use of other materials.

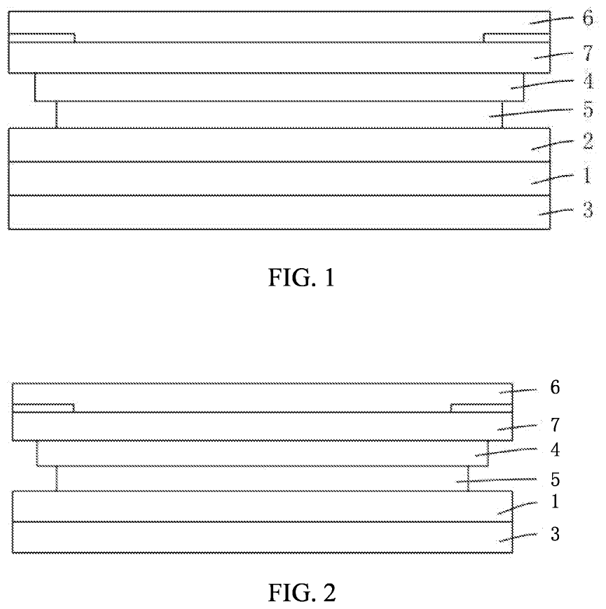

Referring to FIG. 1, a display panel is provided in the related art, and the display panel includes: a panel body 1, a backplane 3 disposed on a back side of the panel body 1, a polarizer 2 disposed on a light exit side of the panel body 1, an ultra-thin glass 4 disposed on a side of the polarizer 2 away from the panel body 1, a first optical adhesive layer 5 disposed between the ultra-thin glass 4 and the polarizer 2, a cover plate 6 disposed on a side of the ultra-thin glass 4 away from the polarizer 2, and a second optical adhesive layer 7 disposed between the cover plate 6 and the ultra-thin glass 2. Protective layers such as the ultra-thin glass 4 and the cover plate 6 are disposed on the light exit side of the panel body 1, and the ultra-thin glass 4 does not cover edges of the panel body 1, and thus the edges cannot be protected. Since the light exit side of the panel body 1 is further covered with the polarizer 2, the polarizer 2 can also protect the edges of the panel body 1. However, a thickness of the display panel is increased, which is not conducive to the demand for thinness and lightness of the display panel.

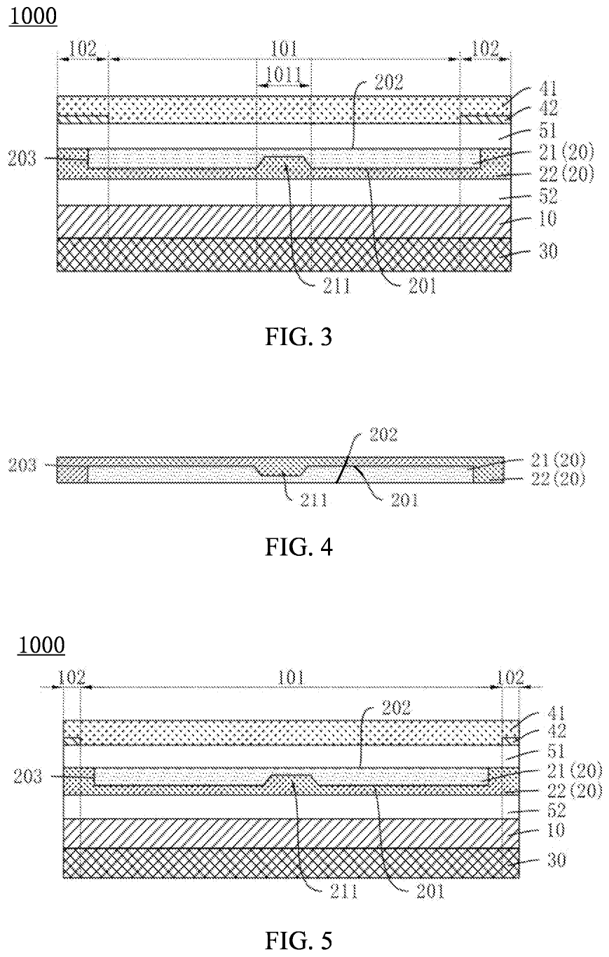

Further, referring to FIG. 2, a display panel having no polarizer is provided in the related art, and the display panel includes: a panel body 1, a backplane 3 disposed on a back side of the panel body 1, an ultra-thin glass 4 disposed on a light exit side of the panel body 1, a first optical adhesive layer 5 disposed between the panel body 1 and the ultra-thin glass 4, a cover plate 6 disposed on a side of the ultra-thin glass 4 away from the panel body 1, and a second optical adhesive layer 7 disposed between the ultra-thin glass 4 the cover plate 6. The panel body 1 is provided therein with a color filter layer to play an anti-reflective role, and thus there is no need to provide a polarizer on the light exit side of the panel body 1. As a result, a thickness of the display panel is effectively reduced. However, since the ultra-thin glass 4 cannot cover edges of the panel body 1, the edges of the panel body I are prone to damage and failure due to impact.

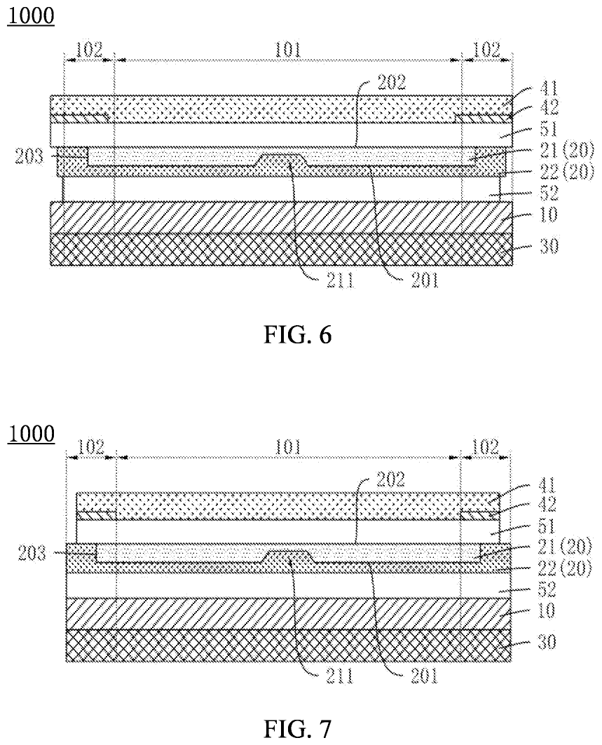

Referring to FIG. 3, a display panel 1000 according to one or more embodiments of the present application includes a panel body 10 and a protective layer 20.

The protective layer 20 is disposed on a light exit side of the panel body 10. The protective layer 20 includes an ultra-thin glass 21 and a protective structure 22. The ultra-thin glass 21 includes a first surface 201 close to the panel body 10 and a plurality of side surfaces 203 connected to the first surface 201. The protective structure 22 covers at least the plurality of side surfaces 203.

Further, an orthographic projection of each side surface 203 on the panel body 10 is offset from a center of the panel body 10, and an absolute value of a difference between a refractive index of the protective structure 22 and a refractive index of the ultra-thin glass 21 is less than or equal to 0.02.

According to the embodiments of the present application, the protective layer 20 is disposed on the light exit side of the panel body 10, the protective layer 20 includes the ultra-thin glass 21 and the protective structure 22, and the protective structure 22 covers the side surfaces 203 of the ultra-thin glass 21. Thus, edges of the panel body 10 that are not covered by the ultra-thin glass 21 may be protected, which reduces the probability of cracking of the edges of the panel body 10. In addition, the absolute value of the difference between the refractive index of the protective structure 22 and the refractive index of the ultra-thin glass 21 is less than or equal to 0.02, which enables optical properties of the protective structure 22 and optical properties of the ultra-thin glass 21 to be consistent. As a result, it allows an interface between the protective structure 22 and the ultra-thin glass 21 to be invisible when being in a display region of the display panel, which may effectively reduce a bezel width of the display panel while ensuring a display effect of the display panel.

In an embodiment of the present application, the display panel has the display region and a non-display region located on at least one side of the display region, and each of the plurality of side surfaces is within the display region.

In an embodiment of the present application, an end of the protective structure away from one of the plurality of side surfaces is flush with an edge of the panel body.

In an embodiment of the present application, respective orthographic projections of the plurality of the side surfaces on the panel body are equally offset from the center of the panel body.

In an embodiment of the present application, the display region includes a bending sub-region, the first surface of the ultra-thin glass is provided with a groove located in the bending sub-region, and the groove is filled with the protective structure.

In an embodiment of the present application, a width of a side of the groove away from the panel body is less than a width of a side of the groove close to the panel body.

In an embodiment of the present application, the display panel further includes a first adhesive layer and a cover plate that are disposed on a side of the protective layer away from the panel body; the cover plate is bonded to a surface of the protective layer away from the panel body through the first adhesive layer.

In an embodiment of the present application, the surface of the protective layer away from the panel body is flat.

In an embodiment of the present application, the display panel further includes a second adhesive layer disposed between the protective layer and the panel body; the protective layer is bonded to the panel body through the second adhesive layer.

In an embodiment of the present application, the protective structure further covers the first surface.

In one embodiment of the present application, the panel body includes: a substrate, a light-emitting functional layer disposed on the substrate, and a color filter layer disposed on a side of the light-emitting functional layer away from the substrate.

The light-emitting functional layer includes a plurality of light-emitting portions, the color filter layer includes a plurality of color resist blocks arranged respectively opposite to the plurality of light-emitting portions, and each of the color resist blocks has a same color as light emissible by one of the plurality of light-emitting portions opposite to the each of the color resist blocks.

In an embodiment of the present application, a distance between each side surface of the plurality of side surfaces and an edge of the panel body close to the each side surface in a direction perpendicular to the each side surface is greater than or equal to 0.05 mm.

In an embodiment of the present application, the display panel further includes: a backplane, a buffer layer and a support layer that are arranged on a side of the panel body away from the protective layer, the backplane is located between the panel body and the buffer layer, and the buffer layer is located between the backplane and the support layer.

Specifically, with continued reference to FIG. 3, the display panel 1000 provided in the embodiments of the present application includes: the panel body 10, the backplane 30 disposed on a back side of the panel body 10, the protective layer 20 disposed on the light exit side of the panel body 10, a second adhesive layer 52 disposed between the panel body 10 and the protective layer 20, a cover plate 41 disposed on a side of the protective layer 20 away from the panel body 10, and a first adhesive layer 51 disposed between the cover plate 41 and the protective layer 20.

It will be understood that the light exit side and the back side of the panel body 10 arc opposite sides of the panel body 10, and the light exit side is a side of the panel body 10 where light is emitted for display.

In an embodiment, each of the first adhesive layer 51 and the second adhesive layer 52 may include an optically clear adhesive (OCA) layer.

In an embodiment, the panel body 10 includes: a substrate, a light-emitting functional layer disposed on the substrate, and a color filter layer disposed on a side of the light-emitting functional layer away from the substrate. The light-emitting functional layer includes a plurality of light-emitting portions, the color filter layer includes a plurality of color resist blocks arranged respectively opposite to the plurality of light-emitting portions, and each of the plurality of color resist blocks has a same color as light emissible by one of the plurality of light-emitting portion opposite to each color resist block. That is to say, the panel body 10 provided in the embodiments of the present application has a depolarizer (Pol-less) structure, and the color filter layer is disposed in the panel body 10 to play a role of anti-reflection, thereby eliminating the arrangement of a polarizer. As a result, the thickness of the display panel is effectively reduced.

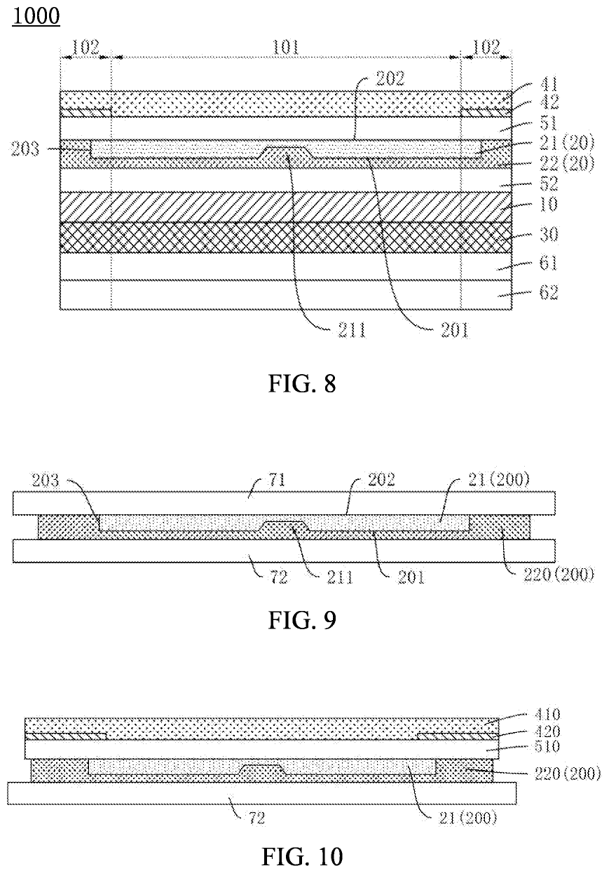

In the embodiments of the present application, referring to FIGS. 3 and 4, the protective layer 20 is located on the light exit side of the panel body 10, the protective layer 20 includes the ultra-thin glass 21 and the protective structure 22, and the ultra-thin glass 21 includes: the first surface 201 close to the panel body 10, a second surface 202 away from the panel body 10, and the plurality of side surfaces 203 connected to the first surface 201. Further, the plurality of side surfaces 203 are connected to and located between the first surface 201 and the second surface 202, the orthographic projection of each side surface 203 on the panel body 10 is offset from the center of the panel body 10. Furthermore, the orthographic projection of the side surface 203 on the panel body 10 is located on a side of an edge of the panel body 10 close to the center of the panel body 10, and respective orthographic projections of the plurality of side surfaces 203 on the panel body 10 are arranged equally offset from the center of the panel body 10.

The protective structure 22 covers at least the plurality of side surfaces 203 of the ultra-thin glass 21. Compared with the related technologies shown in FIGS. 1 and 2, the protective structure 22 can cover the side surfaces 203 of the ultra-thin glass 21, and thus a total area of the edges of the panel body 10 being covered is increased. As a result, the protection effect on the edges of the panel body 10 is improved, and the yield rate of the display panel is improved.

Furthermore, since each side surface 203 of the ultra-thin glass 21 is retracted from an edge of the panel body 10, the probability of cracking of the ultra-thin glass 21 during a cutting process may be reduced.

In the embodiments of the present application, the absolute value of the difference between the refractive index of the protective structure 22 and the refractive index of the ultra-thin glass 21 is less than or equal to 0.02, so that the optical properties of the protective structure 22 are the same as or similar to the optical properties of the ultra-thin glass 21. Therefore, there is no optical change when light passes through the protective structure 22 and the ultra-thin glass 21. In the embodiments of the present application, an interface between the protective structure 22 and the ultra-thin glass 21 may be arranged in the display region of the display panel, and the interface is not visible when the display panel performs display, which may effectively reduce the bezel width of the display panel.

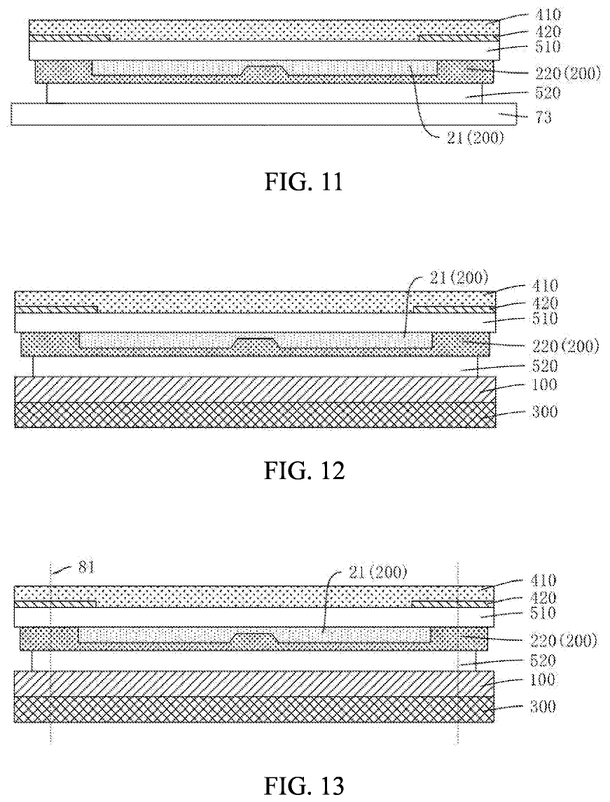

In an embodiment, referring to FIG. 5, the display panel 1000 has the display region 101 and the non-display region 102 located on at least one side of the display region 101, the side surfaces 203 are located in the display region 101, and the interface between the protective structure 22 and the ultra-thin glass 21 is not visible when the display panel performs display. That is, the protective structure 22 covering the side surfaces 203 is at least partially located in the display region 101. Due to the fitting tolerance and a cutting reserve space, a certain distance needs to be maintained between each side surface 203 of the ultra-thin glass 21 and an edge of the display panel close to the side surface 203. Therefore, when the side surfaces 203 of the ultra-thin glass 21 is arranged in the display region 101 in the embodiments of the present application, the edges of the display panel may also retract towards the display region 101, so that a distance between the edge of the display panel and the display region 101 is reduced. That is, a width of the non-display region 102 is reduced. As a result, the bezel width of the display panel is reduced, which is beneficial to realizing a display panel with narrow bezel.

In other embodiments of the present application, referring to FIG. 3, a difference from the embodiments shown in FIG. 5 is that the side surfaces 203 of the ultra-thin glass 21 can also be located in the non-display region 102.

The display panel 1000 further includes a light-shielding member 42 disposed on a side of the cover plate 41 close to the panel body 10, and the light-shielding member 42 is located in the non-display region 102, so that the light-shielding member 42 may play a role in blocking light and blocking devices in the display panel.

In an embodiment, the refractive index of the ultra-thin glass 21 may be greater than or equal to 1.5 and less than or equal to 1.51, the refractive index of the protective structure 22 may be greater than or equal to 1.5 and less than or equal to 1.52, and the absolute value of the difference between the refractive index of the protective structure 22 and the refractive index of the ultra-thin glass 21 is less than or equal to 0.02. Optionally, a material of the protective structure 22 may include a resin material, such as polyimide or polymethyl methacrylate.

It will be noted that, since optical properties of an OCA and optical properties of a polyethylene terephthalate material are quite different from the optical properties of the ultra-thin glass 21 (for example, a refractive index of the OCA and a refractive index of the polyethylene terephthalate material are quite different from the refractive index of the ultra-thin glass 21), the protective structure 22 provided in the embodiments of the present application cannot be fabricated by using the OCA or the polyethylene terephthalate material. In a case where the side surface 203 of the ultra-thin glass 21 is disposed in the display region 101, an interface between the ultra-thin glass 21 and the OCA or an interface between the ultra-thin glass 21 and the polyethylene terephthalate material is visible, which will seriously affect the display effect of the display panel. In an embodiment, referring to FIG. 3, The display region 101 of the display panel 1000 includes a bending sub-region 1011, and the display panel 1000 may be bent at a position in the bending sub-region 1011 to realize a bendable display panel. The first surface 201 of the ultra-thin glass 21 is provided with a groove 211 located in the bending sub-region 1011, and the groove 211 is filled with the protective structure 22. In the embodiment of the present application, the ultra-thin glass 21 is provided with the groove 211 located in the bending sub-region 1011, and thus the bending performance of the ultra-thin glass 21 is improved. The groove 211 is filled with the protective structure 22, thereby reducing the probability of an impression happening to the display panel due to the groove 211, and improving the supporting performance of the display panel at the groove 211.

In an embodiment, an elastic modulus of the protective structure 22 may be less than an clastic modulus of the ultra-thin glass 21, thereby improving the supporting performance of the display panel at the groove 211 and also improving the bending performance of the display panel.

In an embodiment, a width of a side of the groove 211 away from the panel body 10 is less than a width of a side of the groove 211 close to the panel body 10. That is, a cross-sectional shape of the groove 211 in a direction perpendicular to the panel body 10 includes a trapezoid, the groove 211 is filled with the protective structure 22, and the absolute value of the difference between the refractive index of the protective structure 22 and the refractive index of the ultra-thin glass 21 is less than or equal to 0.02. As a result, it may avoid that an optical effect is generated in the process of filling the groove 211 due to the difference between the refractive index of the protective structure 22 and the refractive index of the ultra-thin glass 21 being too large, and the optical effect is similar to that of a microlens structure. Therefore, a relative large optical difference between the bending sub-region 1011 and another region of the display panel is avoided, and the display uniformity of the display panel is improved.

In other embodiments of the present application, in a case where the cross-sectional shape of the groove 211 is another shape, such as a rectangle, the refractive index of the protective structure 22 is close to or equal to the refractive index of the ultra-thin glass 21 in the embodiments of the present application, which may also avoid an interface at a side wall of the groove 211 from being visible in the display panel, thereby improving the display effect of the display panel.

Further, in an embodiment, the protective structure 22 further covers the first surface 201 of the ultra-thin glass 21. That is, the protective structure 22 can cover the side surfaces 203 and the first surface 201 of the ultra-thin glass 21 and fill the groove 211 in a continuous manner. As a result, a structure is formed, the ultra-thin glass 21 is half surrounded by the structure, and only the second surface 202 of the ultra-thin glass 21 is exposed. Therefore, it may avoid the occurrence of bubbles that are easily caused by fully covering the ultra-thin glass 21 during the manufacturing process, thereby improving the display effect of the display panel.

The surface of the protective layer 20 close to the panel body 10 is bonded to the panel body 10 through the second adhesive layer 52, and the cover plate 41 is bonded to the second surface 202 of the ultra-thin glass 21 through the first adhesive layer 51.

It will be noted that, a surface of the protective structure 22 covering the side surfaces 203 of the ultra-thin glass 21 away from the panel body 10 is flush with a surface of the ultra-thin glass 21 away from the panel body 10. That is, the surface of the protective layer 20 away from the panel body 10 is flat. When the first adhesive layer 51 is bonded to the second surface 202, an interface extending along a direction of the panel body 10 approaching the protective layer 20 will not be formed on the side surfaces 203 of the ultra-thin glass 21, thereby avoiding optical abnormalities at the side surfaces 203 when the side surfaces 203 are located in the display region 101.

In an embodiment, since the first adhesive layer 51 is fabricated with using the OCA, a large difference exists between optical properties of the first adhesive layer 51 and optical properties of the ultra-thin glass 21, and the second surface 202 is a flat surface. As a result, it may avoid that an interface extending along a thickness direction of the display panel 1000 exists between the ultra-thin glass 21 and the first adhesive layer 51. Therefore, it may avoid that a visible interface exists between the ultra-thin glass 21 and the first adhesive layer 51 in the display panel, thereby improving the display effect of the display panel.

In an embodiment of the present application, referring to FIG. 3, an end of the protective structure 22 away from a side surface 203 is flush with an edge of the panel body 10. That is, the protective structure 22 may cover all edges of the panel body 10, thereby effectively improving the protection effect of the protective layer 20 on the panel body 10.

Further, edges of the cover plate 41, the protective layer 20, the panel body 10 and the backplane 30 are all flush with each other.

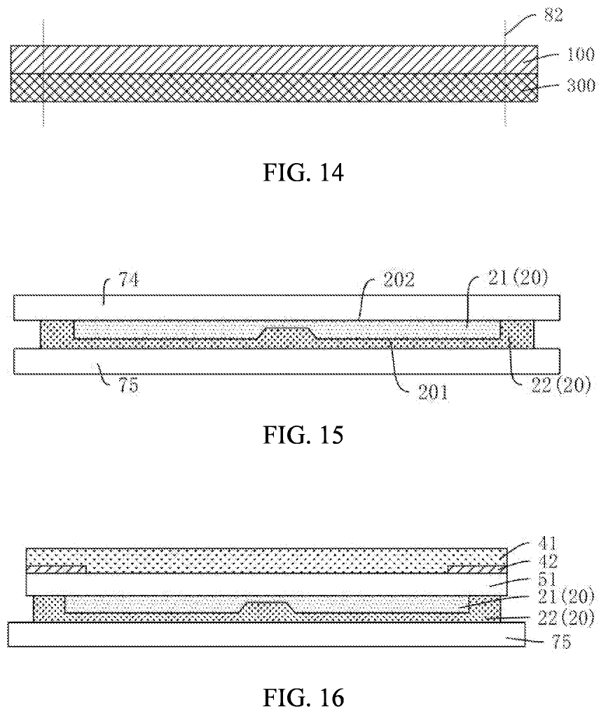

In another embodiment of the present application, referring to FIG. 6, the end of the protective structure 22 away from the side surface 203 is located on a side of the edge of the panel body 10 close to the center of the panel body 10. That is, the end of the protective structure 22 away from the side surface 203 is retracted from the edge of the panel body 10.

Further, edges of the cover plate 41, the panel body 10 and the backplane 30 are all flush with each other.

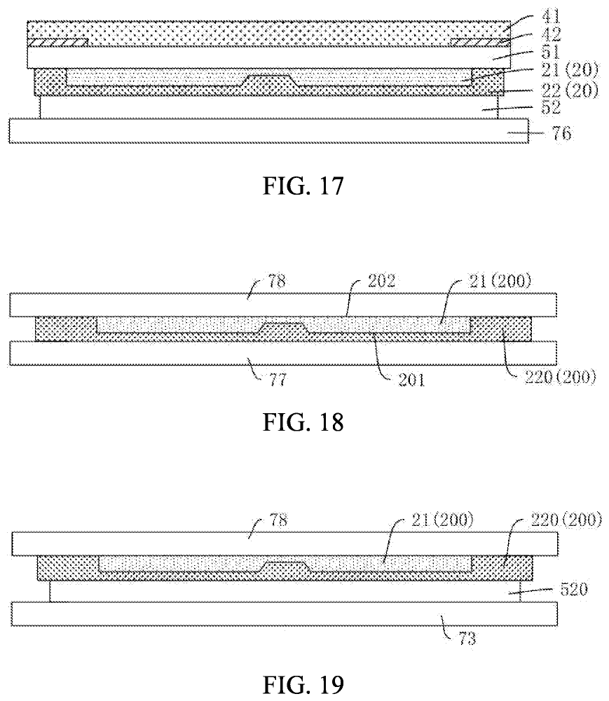

In another embodiment of the present application, referring to FIG. 7, the end of the protective structure 22 away from the side surface 203 is flush with the edge of the panel body 10. That is, the protective structure 22 may cover all edges of the panel body 10, thereby effectively improving the protection effect of the protective layer 20 on the panel body 10.

Further, edges of the protective layer 20, the panel body 10 and the backplane 30 are all flush with each other, and an edge of the cover plate 41 is retracted from an edge of the protective layer 20.

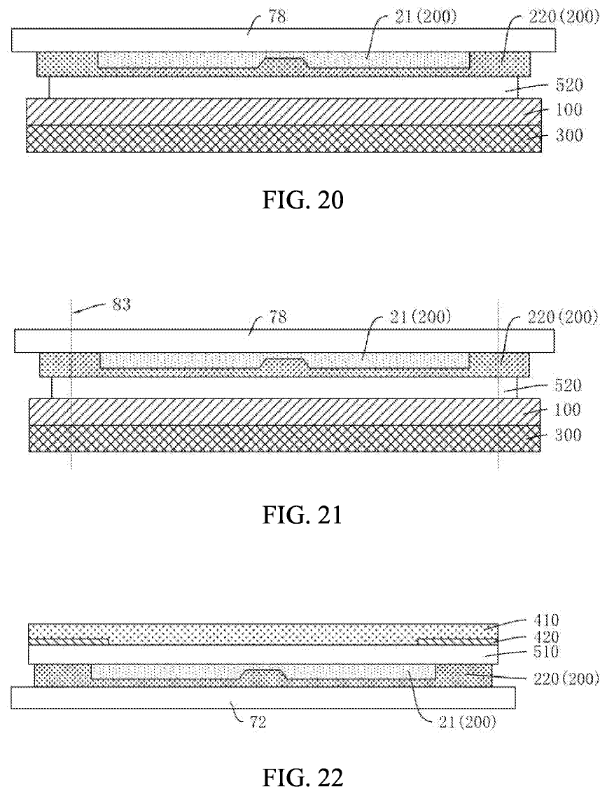

In another embodiment of the present application, referring to FIG. 8, a difference from the embodiments shown in FIG. 3 is that the display panel 1000 further includes a buffer layer 61 disposed on a side of the backplane 30 away from the panel body 10 and a support layer 62 disposed on a side of the buffer layer 61 away from the backplane 30.

A material of the buffer layer 61 may include at least one of silicon oxide, silicon nitride, or silicon oxynitride. For example, the buffer layer 61 may include a structure in which a silicon oxide layer and a silicon nitride layer are alternately stacked. A material of the support layer 62 may include a carbon fiber material, so that a back side of the panel body 10 has sufficient stress buffering and supporting effects, and the panel body 10 has a relative good bending performance.

Base on the above, in an embodiment, the distance between each side surface 203 and an edge of the panel body 10 close to the side surface 203 in a direction parallel to the panel body 10 is greater than or equal to 0.05 mm to avoid undesirable phenomena such as cracking of the ultra-thin glass 21 during the cutting process of the display panel. Furthermore, the distance from the side surface 203 to the edge of the panel body 10 in the direction parallel to the panel body 10 is greater than or equal to 0.2 mm.

In addition, embodiments of the present application also provide a method of manufacturing the display panel described in the embodiments above.

Specifically, in an embodiment, with reference to FIGS. 3, 9 and 10 to 13, the method of manufacturing the display panel 1000 includes following steps.

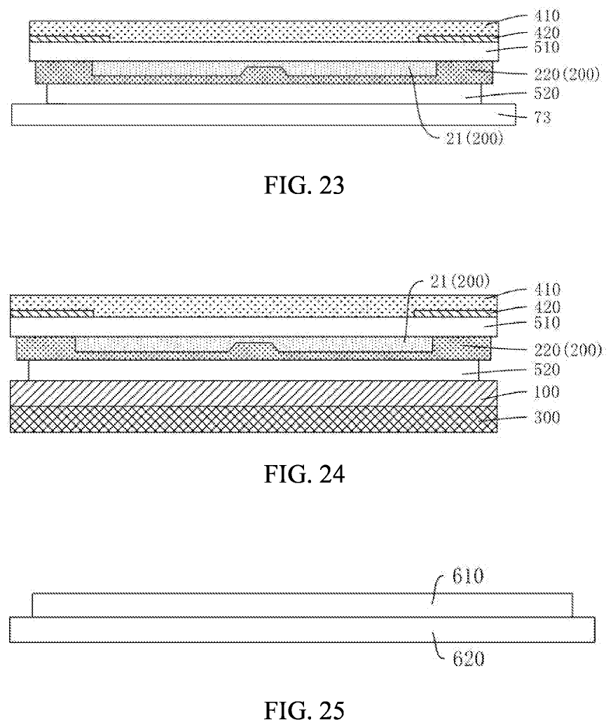

As shown in FIG. 9, a protective layer motherboard 200 is provided, the protective layer motherboard 200 includes ultra-thin glass 21 and a protective cover layer 220 covering the ultra-thin glass 21. The ultra-thin glass 21 includes: a first surface 201 and a second surface 202 that are oppositely arranged, and a plurality of side surfaces 203 that are connected to and located between the first surface 201 and the second surface 202, and the protective cover layer 220 continuously covers the first surface 201 of the ultra-thin glass 21 and the plurality of side surfaces 203, and the protective cover layer 220 does not cover the second surface 202 of the ultra-thin glass 21 to avoid bubbles generated when the protective cover layer 220 further covers of the ultra-thin glass 21.

A first release film 71 and a first protective film 72 are respectively attached to the protective layer motherboard 200 on opposite sides. The first release film 71 is attached on the second surface 202 of the ultra-thin glass 21, and the first protective film 72 is attached on the first surface 201 of the ultra-thin glass 21.

As shown in FIG. 10, the protective layer motherboard 200 is attached to a cover motherboard 410. The first release film 71 is firstly removed, and a surface of the protective layer motherboard 200 from which the first release film 71 is removed is bonded to the cover motherboard 410 with using a first adhesive material layer 510.

A light-shielding layer 420 is provided on a side of the cover motherboard 410 close to the protective layer motherboard 200.

Next, as shown in FIG. 11, the first protective film 72 on a side of the protective layer motherboard 200 is removed, a second adhesive material layer 520 is attached to the side of the protective layer motherboard 200 away from the cover motherboard 410, and a second protective film 73 is provided on a side of the second adhesive material layer 520 away from the protective layer motherboard 200.

Then, as shown in FIG. 12, the second protective film 73 is removed, and a panel body motherboard 100 and a backplane motherboard 300 are sequentially arranged on the side of the second adhesive material layer 520 away from the protective layer motherboard 200.

Furthermore, cutting is performed along a first cutting line 81 as shown in FIG. 13 to obtain the display panel as shown in FIG. 3. The first cutting line 81 is spaced apart from the ultra-thin glass 21 in the protective layer motherboard 200, so to avoid cracking of the ultra-thin glass 21 during the cutting process. As shown in FIG. 3, after the cutting process, edges of the panel body 10, the protective layer 20, the backplane 30, and the cover plate 41 are all flush with each other.

In another embodiment of the present application, referring to FIGS. 6 and 14 to 17, the method of manufacturing the display panel includes following steps.

First, a panel body motherboard 100 and a backplane motherboard 300 shown in FIG. 14 are cut, specifically along a second cutting line 82, so as to obtain the panel body 10 and the backplane 30 as shown in FIG. 6.

A protective layer 20 as shown in FIG. 15 is provided, and a second release film 74 and a third protective film 75 are respectively attached to the protective layer 20 on opposite sides. The third protective film 75 is attached to a side of the protective layer 20 on which the first surface 201 is located, and the second release film 74 is attached to a side of the protective layer 20 on which the second surface 202 is located.

Next, as shown in FIG. 16, the second release film 74 is removed, and the side of the protective layer 20 from which the second release film 74 is removed is attached to a cover plate 41.

Then, the third protective film 75 is removed, a second adhesive layer 52 is attached to the side of the protective layer 20 away from the cover plate 41, and a fourth protective film 76 is attached to a side of the second adhesive layer 52 away from the protective layer 20.

Furthermore, as shown in FIG. 6, the fourth protective film 76 is removed, the panel body 10 and the backplane 30 shown in FIG. 14 are arranged on the side of the second adhesive layer 52 away from the protective layer 20, and the panel body 10 is located on the side of the protective layer 20 away from the second adhesive layer 52, and the backplane 30 is located on the side of the panel body 10 away from the second adhesive layer 52.

In yet another embodiment of the present application, referring to FIGS. 7 and 18 to 21, the method of manufacturing the display panel includes following steps.

A protective layer motherboard 200 as shown in FIG. 18 is provided. A third release film 77 and a fifth protective film 78 are respectively attached to the protective layer motherboard 200 on opposite sides. The third release film 77 is attached on the first surface 201 of the ultra-thin glass 21, and the fifth protective film 78 is attached on the second surface 202 of the ultra-thin glass 21.

As shown in FIG. 19, the third release film 77 on a side of the protective layer motherboard 200 is removed, a second adhesive material layer 520 is attached to the side of the protective layer motherboard 200 from which the third release film 77 is removed, and a second protective film 73 is attached to a side of the second adhesive material layer 520 away from the protective layer motherboard 200.

Next, as shown in FIG. 20, the second protective film 73 is removed, and then a panel body motherboard 100 is attached to a side of the second adhesive material layer 520 away from the protective layer motherboard 200, and a backplane motherboard 300 is attached to a side of the panel body motherboard 100 away from the protective layer motherboard 200.

Then, cutting is performed along a third cutting line 83 shown in FIG. 21, and the third cutting line 83 is spaced apart from the ultra-thin glass 21 in the protective layer motherboard 200 to avoid cracking of the ultra-thin glass 21 during the cutting process. As shown in FIG. 7, after the cutting process, edges of the panel body 10, the protective layer 20, and the backplane 30 are all flush with each other, and an edge of the cover plate 41 is retracted from an edge of the protective layer 20.

Furthermore, as shown in FIG. 7, the fifth protective film 78 is removed, and then the cover plate 41 is attached to a side of the protective layer 20 away from the panel body 10, and the cover plate 41 is bonded to the protective layer 20 through the first adhesive layer 51.

In yet another embodiment of the present application, referring to FIGS. 8, 9 and 22 to 27, the method of manufacturing the display panel includes following steps.

The protective layer motherboard 200 as shown in FIG. 9 is provided, and then, the first release film 71 on the side of the protective layer motherboard 200 is removed; as shown in FIG. 22, a cover motherboard 410 is attached to the side of the protective layer motherboard 200 from which the first release film 71 is removed, and the cover motherboard 410 is bonded to the protective layer motherboard 200 through a first adhesive material layer 510.

Next, as shown in FIG. 23, the first protective film 72 is removed, and a second adhesive material layer 520 is attached to the side of the protective layer motherboard 200 away from the cover motherboard 410, and a second protective film 73 is attached to a side of the second adhesive material layer 520 away from the protective layer motherboard 200.

Then, as shown in FIG. 24, the second protective film 73 is removed, and a panel body motherboard 100 and a backplane motherboard 300 are sequentially arranged on the side of the second adhesive material layer 520 away from the protective layer motherboard 200.

Further, as shown in FIG. 25, a buffer layer motherboard 610 and a support layer motherboard 620 that are stacked are provided.

As shown in FIG. 26, the buffer layer motherboard 610 and the support layer motherboard 620 that are stacked are attached to a side of the backplane motherboard 300 away from the panel body motherboard 100, and the buffer layer motherboard 610 is located between the backplane motherboard 300 and the support layer motherboard 620.

Furthermore, cutting is performed along a fourth cutting line 84 shown in FIG. 27 to obtain the display panel as shown in FIG. 8. The fourth cutting line 84 is spaced apart from the ultra-thin glass 21 in the protective layer motherboard 200, so as to avoid cracking of the ultra-thin glass 21 during the cutting process. As shown in FIG. 8, after the cutting process, edges of the panel body 10, the protective layer 20, the backplane 30, the cover plate 41, the buffer layer 61 and the support layer 62 are all flush with each other.

To sum up, in the embodiments of the present application, the protective layer 20 is disposed on the light exit side of the panel body 10, and the protective layer 20 includes the ultra-thin glass 21 and the protective structure 22; each side surface 203 of the ultra-thin glass 21 is located on a side of an edge of the panel body 10 close to the center of the panel body 10, and the protective structure 22 covers the side surfaces 203 of the ultra-thin glass 21. In an aspect, edges of the panel body 10 that are not covered by the ultra-thin glass 21 are protected. In another aspect, a spacing exists between the ultra-thin glass 21 and the edge of the panel body 10, which avoids the ultra-thin glass 21 from cracking during the cutting process. In addition, the absolute value of the difference between the refractive index of the protective structure 22 and the refractive index of the ultra-thin glass 21 is less than or equal to 0.02, which enables the optical properties of the protective structure 22 and the optical properties of the ultra-thin glass 21 to be consistent. As a result, it allows the interface between the protective structure 22 and the ultra-thin glass 21 to be invisible when being in the display region of the display panel, which may effectively reduce the bezel width of the display panel while ensuring the display effect of the display panel.

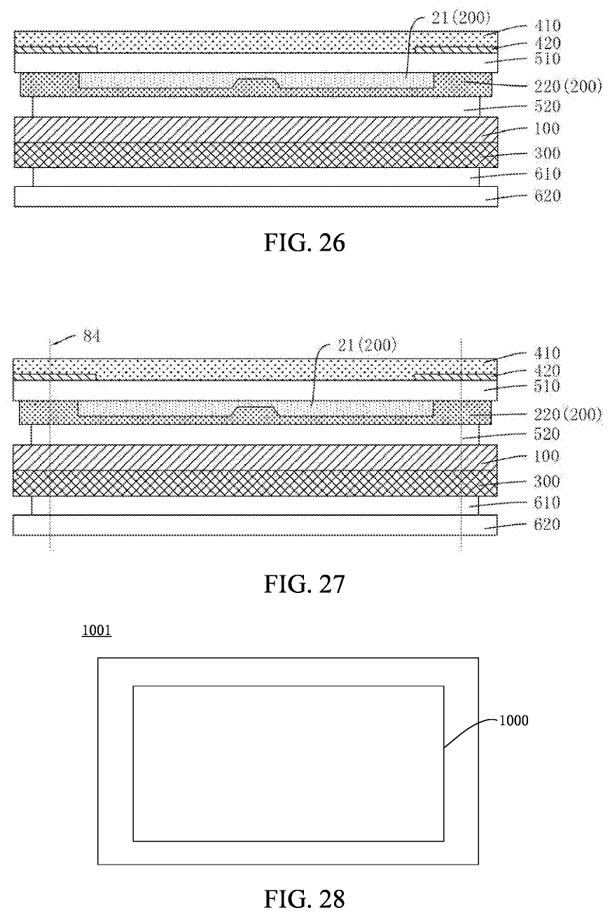

In addition, one or more embodiments of the present application provide a display apparatus. As shown in FIG. 28, the display apparatus 1001 includes the display panel 1000 according to any of the above embodiments.

In an embodiment, the display apparatus provided in the embodiments of the present application may include a mobile phone, a computer, a television, a tablet, and other display apparatus.

It will be understood that the display apparatus provided in the embodiments of the present application includes the display panel described in the embodiments above. Therefore, the display apparatus has same beneficial effects as the display panel described in the above embodiments, which will not be repeated here.

Among the above embodiments, each embodiment is described with its own emphasis. For parts that are not described in detail in a certain embodiment, reference can be made to relevant descriptions of other embodiments.

Some embodiments of the present application have been described in detail above. The description of the above embodiments merely aims to help to understand the present application. Many modifications or equivalent substitutions with respect to the embodiments may occur to those of ordinary skill in the art based on the present application. Thus, these modifications or equivalent substitutions shall fall within the scope of the present application.

What is claimed is:

1. A display panel comprising:
a panel body; and
a protective layer disposed on a light exit side of the panel body, wherein the protective layer comprises an ultra-thin glass and a protective structure, the ultra-thin glass comprises a first surface close to the panel body and a plurality of side surfaces each connected to the first surface, and the protective structure covers at least the plurality of side surfaces,
wherein an orthographic projection of each of the plurality of side surfaces on the panel body is offset from a center of the panel body, and an absolute value of a difference between a refractive index of the protective structure and a refractive index of the ultra-thin glass is less than or equal to 0.02.

2. The display panel according to claim 1, wherein the display panel has a display region and a non-display region located on at least one side of the display region, and each of the plurality of side surfaces is within the display region.

3. The display panel according to claim 1, wherein an end of the protective structure away from one of the plurality of side surfaces is flush with an edge of the panel body.

4. The display panel according to claim 1, wherein respective orthographic projections of the plurality of the side surfaces on the panel body are equally offset from the center of the panel body.

5. The display panel according to claim 2, wherein the display region comprises a bending sub-region, the first surface of the ultra-thin glass is provided with a groove located in the bending sub-region, and the groove is filled with the protective structure.

6. The display panel according to claim 5, wherein a width of a side of the groove away from the panel body is less than a width of a side of the groove close to the panel body.

7. The display panel according to claim 1, further comprising a first adhesive layer and a cover plate that are disposed on a side of the protective layer away from the panel body,
wherein the cover plate is bonded to a surface of the protective layer away from the panel body through the first adhesive layer.

8. The display panel according to claim 7, wherein the surface of the protective layer away from the panel body is flat.

9. The display panel according to claim 1, further comprising a second adhesive layer disposed between the protective layer and the panel body,
wherein the protective layer is bonded to the panel body through the second adhesive layer.

10. The display panel according to claim 1, wherein the protective structure further covers the first surface.

11. The display panel according to claim 1, wherein the panel body comprises: a substrate, a light-emitting functional layer disposed on the substrate, and a color filter layer disposed on a side of the light-emitting functional layer away from the substrate,
wherein the light-emitting functional layer comprises a plurality of light-emitting portions, the color filter layer comprises a plurality of color resist blocks arranged respectively opposite to the plurality of light-emitting portions, and each of the color resist blocks has a same color as light emissible by one of the plurality of light-emitting portions opposite to the each of the color resist blocks.

12. The display panel according to claim 1, wherein a distance between each side surface of the plurality of side surfaces and an edge of the panel body close to the each side surface in a direction perpendicular to the each side surface is greater than or equal to 0.05 mm.

13. The display panel according to claim 1, further comprising: a backplane, a buffer layer and a support layer that are arranged on a side of the panel body away from the protective layer, wherein the backplane is located between the panel body and the buffer layer, and the buffer layer is located between the backplane and the support layer.

14. A display apparatus, comprising a display panel,
wherein the display panel comprises:
a panel body; and
a protective layer disposed on a light exit side of the panel body, wherein the protective layer comprises an ultra-thin glass and a protective structure, the ultra-thin glass comprises a first surface close to the panel body and a plurality of side surfaces each connected to the first surface, and the protective structure covers at least the plurality of side surfaces,
wherein an orthographic projection of each of the plurality of side surfaces on the panel body is offset from a center of the panel body, and an absolute value of a difference between a refractive index of the protective structure and a refractive index of the ultra-thin glass is less than or equal to 0.02.

15. The display apparatus according to claim 14, wherein the display panel has a display region and a non-display region located on at least one side of the display region, and each of the plurality of side surfaces is within the display region.

16. The display apparatus according to claim 14, wherein an end of the protective structure away from one of the plurality of side surfaces is flush with an edge of the panel body.

17. The display apparatus according to claim 14, wherein respective orthographic projections of the plurality of the side surfaces on the panel body are equally offset from the center of the panel body.

18. The display apparatus according to claim 15, wherein the display region comprises a bending sub-region, the first surface of the ultra-thin glass is provided with a groove located in the bending sub-region, and the groove is filled with the protective structure.

19. The display apparatus according to claim 14, wherein the protective structure further covers the first surface.

20. The display apparatus according to claim 14, wherein the panel body comprises a substrate, a light-emitting functional layer disposed on the substrate, and a color filter layer disposed on a side of the light-emitting functional layer away from the substrate,
wherein the light-emitting functional layer comprises a plurality of light-emitting portions, the color filter layer comprises a plurality of color resist blocks arranged respectively opposite to the plurality of light-emitting portions, and each of the color resist blocks has a same color as light emissible by one of the light-emitting portions opposite to the each of the color resist blocks.
